(19) United States
(12) Patent Application Publication
(10) Pub. No.: US 2007/0047338 A1
(43) Pub. Date: Mar. 1, 2007

(54) External delayed switch apparatus for cooling fans

(75) Inventor: Chin-Wen Chou, Taipei Hsien (TW)

Correspondence Address: BIRCH STEWART KOLASCH & BIRCH, PO BOX 747, FALLS CHURCH, VA, 22040-0747, US

(73) Assignee: Zippy Technology Corp.

(21) Appl. No.: 11/202,024

(22) Filed: Aug. 12, 2005

(51) Int. Cl. G11C 7/00

(52) U.S. Cl. 365/194

(57) ABSTRACT

An external delayed switch apparatus for cooling fans aims to provide electric power to at least one cooling fan located in a computer to continuously operate to lower temperature when the computer is shut down. The computer has a power supply which includes a standby power system and a main power supply system to provide electric power for computer operation. The external delayed switch apparatus includes a power converter which is electrically connected to an AC power input source and transforms AC power to DC power required by the cooling fan and an external controller which provides an operation parameter to the power converter to determine operation time of the cooling fan driven by the DC power.

### FIELD OF THE INVENTION

The present invention relates to an external delayed switch apparatus for cooling fans and particularly to an external delayed switch apparatus installed in a computer to provide electric power to drive cooling fans to lower temperature when the computer is in a shutdown condition.

### BACKGROUND OF THE INVENTION

In response to a common problem occurred to the computer that residual heat remained to be dispelled even when the computer is shut down, many schemes have been proposed in the prior art. For instance, R.O.C. Patent Publication No. 392106 discloses a technique which outputs a fan switch control signal through a south bridge chip set and a control circuit to a fan power supply switch and a switch circuit to transfer power supply for cooling fans when the machine is in a shut down condition. R.O.C patent publication No. 400968 discloses a technique which has a power supply that includes a standby power system, a main power system and cooling fans and is electrically connected to a delayed switch apparatus which is switchable when the computer is ON or OFF to provide different electric power to drive the cooling fans. It is widely adopted in the present market. Based on this technique, a number of variations have been developed, such as R.O.C. Patent Publication No. 572579, No. 568300, No. M247876 and No. M268654.

### SUMMARY OF THE INVENTION

The primary object of the present invention is to solve the aforesaid disadvantages. The invention is a novel technique based on R.O.C Patent Publication No. 400968. The invention provides an improvement that includes an external delayed switch apparatus. It can provide electric power to maintain continuous operation of cooling fans when a computer is shut down. It also allows users to decide the number of cooling fans to be deployed and whether to turn off the external delayed switch apparatus according to environmental requirement.

To achieve the foregoing object, the external delayed switch apparatus of the invention includes a power converter which is electrically connected to an AC power input source and transforms the AC power to DC power required by the cooling fans, and an external controller which provides an operation parameter to the power converter to determine the operation time of the cooling fans driven by the DC power.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is an exploded view of the present invention.

FIG. 2 is a perspective view of the present invention.

### DETAILED DESCRIPTION OF THE PREFERRED EMBODIMENT

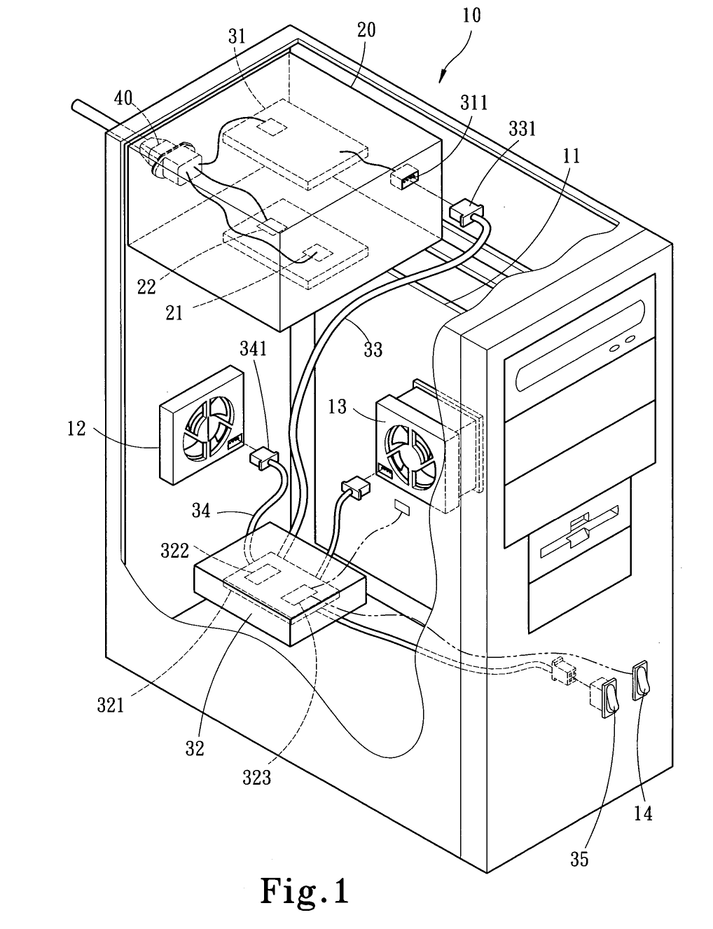

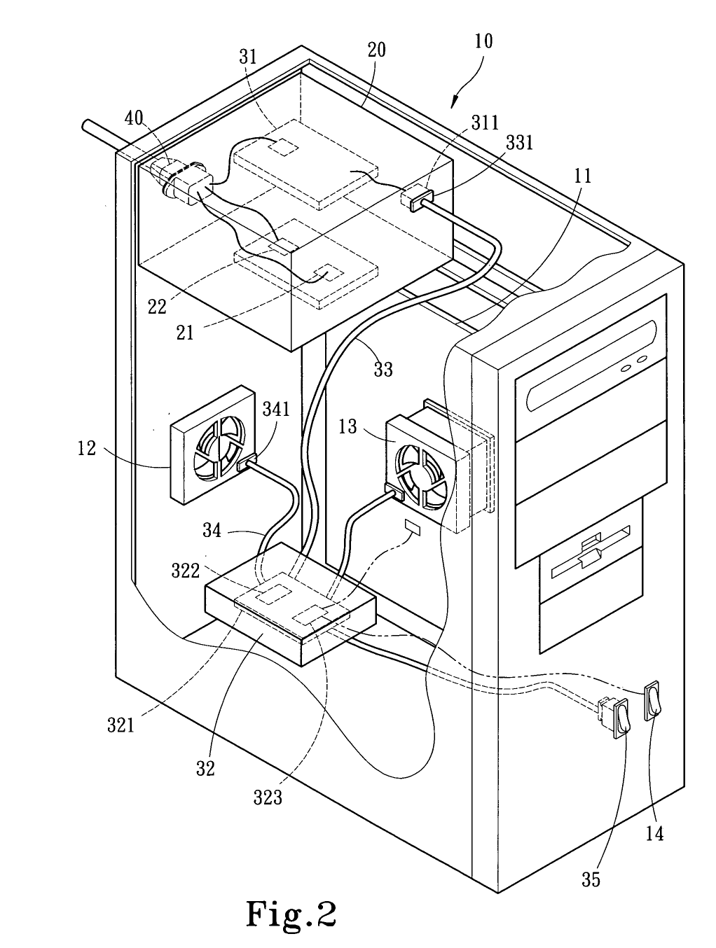

Please refer to FIGS. 1 and 2, the invention aims to provide an external delayed switch apparatus for cooling fans 12 and 13 that are located in a computer 10 so that at least one of the cooling fan 12 and 13 still can receive electric power and operate to lower the temperature when the computer 10 is in a shutdown condition. The computer 10 has a power supply 20 which includes a standby power system 22 and a main power supply system 21 to provide operation power for the computer 10. The external delayed switch apparatus mainly includes a power converter 31 which is electrically connected to an AC power input source 40 and transforms the AC power to DC power required by the cooling fans 12 and 13. The power converter 31 contains at least one full-wave or half-wave rectifier and a filter capacitor. The power converter 31 is located in the power supply 20, and coupled in parallel with the standby power system 22 and connected electrically to the AC power input source 40. The power supply 20 has an electric port 311 on the exterior to allow the power converter 31 to output the DC power (the embodiment shown in the drawings indicate the electric port 311. The power converter 31 may also directly output power outside the power supply 20 through a power cord which has an electric connector on a distal end. This is a technique known in the art, thus details are omitted). The computer 10 has an external controller 32 connecting to the electric port 311. The external controller 32 provides an operation parameter to the power converter 31 to determine the operation time of the cooling fans 12 and 13 driven by the DC power. The external controller 32 includes a circuit board 321 and a timing circuit 322 located on the circuit board 321. The circuit board 321 is connected to power cords 33 and 34 that have respectively an electric connector 331, 341 to be coupled with the electric port 311 to deliver electric power to the cooling fans 12 and 13. The timing circuit 322 is a timer circuit, a temperature detection circuit or a combination thereof. The external controller 32 further has an ON/OFF circuit 323 to receive remote ON/OFF signals of the computer 10. The remote ON/OFF signals are provided by a mainboard 11 or a switch control circuit 14 of the computer 10. The external delayed switch apparatus further is connected to an ON/OFF switch 35 installed on a chassis of the computer 10.

When in use, the external controller 32 can control power output through the multiple power cords 33 and 34 according to the maximum number of the cooling fans 12 and 13 being installed in the computer 10. Because the invention adopts the external connection design, the cooling fans 12 and 13 can be effectively controlled in response to upgrade requirement of the computer 10. In special environments, such as the computer 10 is installed in a closed space or a location where sunshine is strong and heat energy is easily generated, the external delayed switch apparatus can be activated via the ON/OFF switch 35 on the chassis of the computer 10 so that cooling operation can be performed for the computer 10 to lower the temperature through the timing circuit 322 of the external controller 32 before the machine is started or any time desired (according to a setting time or temperature) without starting or stopping the computer 10. After the computer 10 has been shut down, if there is no need to defer switch off of the cooling fans 12 and 13, the external delayed switch apparatus can be turned off through the ON/OFF switch 35.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An external delayed switch apparatus for cooling fans to provide electric power for at least one cooling fan in a computer to continuously operate to lower temperature when the computer is shut down, the computer having a power supply which includes a standby power system and a main power supply system to provide electric power for computer operation, the external delayed switch apparatus comprising:
a power converter which is electrically connected to an AC power input source to transform AC power to DC power required by the cooling fan; and
an external controller located in the computer to provide an operation parameter to the power converter to determine operation time of the cooling fan driven by the DC power.

2. The external delayed switch apparatus of claim 1, wherein the power converter includes one filter capacitor and at least one of full-wave rectifier and half-wave rectifier.

3. The external delayed switch apparatus of claim 1, wherein the power converter is located in the power supply and coupled with the standby power system in a parallel manner and connected to the AC power input source.

4. The external delayed switch apparatus of claim 3, wherein the power supply has an electric port on the exterior for the power converter to output the DC power.

5. The external delayed switch apparatus of claim 4, wherein the external controller includes a circuit board and a timing circuit located on the circuit board to generate the operation parameter, the circuit board being coupled with a power cord to connect to the electric port to output electric power to the cooling fan.

6. The external delayed switch apparatus of claim 5, wherein the timing circuit is a timer circuit.

7. The external delayed switch apparatus of claim 5, wherein the timing circuit is a temperature detection circuit.

8. The external delayed switch apparatus of claim 5, wherein the timing circuit is a combination circuit consisting of a timer circuit and a temperature detection circuit.

9. The external delayed switch apparatus of claim 5, wherein the external controller includes an ON/OFF circuit to receive ON/OFF signals of the computer.

10. The external delayed switch apparatus of claim 9, wherein the computer ON/OFF signals are provided by a mainboard of the computer.

11. The external delayed switch apparatus of claim 9, wherein the computer ON/OFF signals are provided by a switch control circuit of the computer.

12. The external delayed switch apparatus of claim 1, wherein the power converter and the cooling fan are bridged by a power cord to transmit the DC power, the external controller being connected to the power cord.

13. The external delayed switch apparatus of claim 12, wherein the external controller includes a circuit board and a timing circuit located on the circuit board.

14. The external delayed switch apparatus of claim 13, wherein the timing circuit is a timer circuit.

15. The external delayed switch apparatus of claim 13, wherein the timing circuit is a temperature detection circuit.

16. The external delayed switch apparatus of claim 13, wherein the timing circuit is a combination circuit consisting of a timer circuit and a temperature detection circuit.

17. The external delayed switch apparatus of claim 13, wherein the external controller includes an ON/OFF circuit to receive ON/OFF signals of the computer.

18. The external delayed switch apparatus of claim 17, wherein the computer ON/OFF signals are provided by a mainboard of the computer.

19. The external delayed switch apparatus of claim 17, wherein the computer ON/OFF signals are provided by a switch control circuit of the computer.

20. The external delayed switch apparatus of claim 1 further being connected to an ON/OFF switch.
